(19) United States
(12) Patent Application Publication
(10) Pub. No.: US 2015/0121837 A1
(43) Pub. Date: May 7, 2015

(54) METHODS FOR APPLYING GRAPHENE COATINGS AND SUBSTRATES WITH SUCH COATINGS

(71) Applicant: Renold Plc, Manchester (GB)

(72) Inventors: Ian Kinloch, Manchester (GB); Amanda Lewis, Manchester (GB); Martin King, Manchester (GB)

(21) Appl. No.: 14/397,470

(22) PCT Filed: Apr. 22, 2013
(86) PCT No.: PCT/GB2013/051016

§ 371 Date: Oct. 27, 2014

(30) Foreign Application Priority Data
Apr. 27, 2012 (GB) 1207515.6
May 2, 2012 (GB) 1207687.3
Jul. 5, 2012 (GB) 1211950.9

(51) Int. Cl. C23C 16/26; C23C 16/56; F16G 13/06; C23C 16/02

(52) U.S. Cl. CPC C23C 16/26; C23C 16/0281; C23C 16/0209; C23C 16/56; F16G 13/06
USPC 59/88; 427/249.6; 428/634

(57) ABSTRACT

A method for applying a graphene coating to a substrate comprising iron or aluminium, the method comprising: providing a metallic layer on a surface of the substrate; and contacting said metallic layer with a source of carbon atoms to provide a graphene coating on the metallic layer. There is also described an iron- or aluminium-containing substrate, for example a component of a chain, with a metallic layer on a surface of the substrate and a graphene coating disposed on said metallic layer.

The present invention relates to a method for applying a graphene coating to a substrate comprising iron or aluminium and such a substrate having a graphene coating. Particular substrates, such as components of chains, having such coatings are also described.

Two of the most ubiquitous metals in use today are aluminium and iron, and their various alloys. Aluminium is the third most abundant element on earth. Its exceptionally low density lends it to a wide range of different applications, such as the aerospace industry where the weight of structural components is of critical importance. Regarding iron, one of its most common alloys is steel. In spite of steel production being heavily dependent upon coal, global use increased by 69% from 2000 to 2010, driven predominantly by a 400% increase in use in China over that period. Methods for improving the wear and corrosion resistance of aluminium- and iron-containing substrates are therefore of significant commercial importance across a wide range of technical fields, such as the aerospace, automotive and pharmaceutical industries. Another such field is the power transmission sector. Despite a wide range of wear and corrosion resistant coatings already being available for use on components of chains, sprockets and associated components, there is a constant drive to develop coatings exhibiting improved performance.

Graphene possesses a wide range of unique properties which has led to a great deal of research to find practical applications which exploit those properties. Not only is graphene the thinnest material currently known, it is also the strongest and most impermeable material. It exhibits the highest thermal conductivity of any material and is a very efficient electrical conductor. Due to its unique electrical properties much of the research to-date has been in the high-tech fields of electronics, opto-electronics and photonics. There is a keen interest to exploit graphene's unique array of properties in other fields, one of which is the field of coatings where the material's exceptionally low thickness, high impermeability and self-lubricating properties could offer great benefits. Unfortunately, the development of graphene-based coatings has been hampered by difficulties in growing or depositing layers of graphene on various substrates, particularly metallic substrates, such as those comprising aluminium or iron.

It is an object of the present invention to address current problems associated with the development of graphene coatings.

According to a first aspect of the present invention there is provided a method for applying a graphene coating to a substrate comprising iron or aluminium, the method comprising:
a. providing a metallic layer on a surface of the substrate; and
b. contacting said metallic layer with a source of carbon atoms to provide a graphene coating on the metallic layer.

By employing the method set out above it is now possible to provide a graphene coating on an aluminium- or iron-containing substrate.

A second aspect of the present invention provides a substrate comprising iron or aluminium with a metallic layer on a surface of the substrate and a graphene coating disposed on said metallic layer.

A third aspect of the present invention provides a chain comprising a plurality of chain link members and a plurality of pins interconnecting said link members, a surface of at least one of the chain link members and/or a surface of at least one of the pins being provided with a graphene coating.

A fourth aspect of the present invention provides a chain comprising a plurality of chain link members, a plurality of pins interconnecting said link members, and a bush and/or roller supported on one or more of the pins, a surface of the bush and/or roller being provided with a graphene coating.

With regard to the third and fourth aspects of the present invention it is preferred that the graphene coating is disposed on a metallic layer provided on the surface of the relevant component or components of the chain, i.e. the chain link member, pin, bush and/or roller. The (or each) surface of the chain component(s) upon which the graphene coating is applied is preferably a wear surface, that is, a surface which is susceptible to wear during use of the chain. It is further preferred that the (or each) surface of the chain component(s) is a surface that is susceptible to corrosion during use of the chain, that is a surface that would be expected to exhibit evidence of corrosion during use of a similar chain which does not have the graphene coating applied to it. Moreover, it is preferred that the (or each) surface of the chain component(s) is a contact surface in need of lubrication during use, i.e. a surface that contacts another component during use of the chain and which would therefore usually be provided with some form of lubrication.

The metallic layer is provided to enable the graphene coating to be provided on the underlying iron- or aluminium-containing substrate.

The metallic layer may comprise a closed D-shell transition metal, or an alloy of such a metal.

Suitable elements which may be included in the metallic layer include cobalt, iron, copper, nickel, silver or gold. A particularly preferred metallic layer is copper metal.

One or more additional elements may also be included, such as titanium or tin. In one embodiment, the metallic layer may comprise multiple elements, such as copper and titanium, in different sub-layers of the metallic layer. By way of example, a layer of titanium may be provided on the substrate surface and then a layer of copper provided on the titanium layer. The underlying layer of, for example, titanium, may stabilise the overlying layer of, for example, copper. In this way, it may be possible to use thinner layers of the upper metal layer than would be possible if the lower layer had not already been provided on the substrate. In another embodiment, the two or more elements may be alloyed together in which case they would therefore reside in the same metallic layer. The alloy may be chosen to have a melting point that is no more than around 100° C. below the temperature at which growth of the graphene layer is to be effected, more preferably a melting point no more than around 50° C. below and most preferably a melting point no more than around 30° C. below the temperature to be used to provide the graphene layer. An exemplary alloy-based metallic layer comprises a copper-tin alloy. Such an alloy is particularly suitable for use when growing a layer of graphene on a steel substrate, such as a steel chain pin. In this example, a suitable alloy may include around 5 to 15 at % (atomic percent) tin in copper, or more preferably around 10 at % tin in copper.

The metallic layer may be a metallic adhesion layer to improve bonding of the graphene coating to the substrate.

The metallic layer may be a barrier layer. The metallic layer may act as a barrier layer by hindering or preventing the diffusion of carbon from the carbon source into the underlying material of the iron or aluminium-based substrate. The metallic layer may catalyse growth of the graphene layer and may thus be considered a catalytic growth layer. While the inventors do not wish to be bound by any particular theory, particularly since catalytic methods for growing graphene layers have not yet been fully characterised in this technical field, it is currently believed that the metallic layer may facilitate a catalytic path for formation of the necessary sp² carbon bonds and/or contribute to or provide surface mobility to aid growth of the graphene layer. Suitable barrier and/or catalytic growth layers may comprise a compound, element or alloy that exhibits a low affinity for carbon or that exhibits a low carbon solubility, such as copper, silver or gold, or a copper-tin alloy.

The metallic layer may incorporate a compound or element that exhibits a high affinity for carbon, such as cobalt, iron or nickel. In such cases, the graphene coating may be provided by supersaturating the metallic layer with carbon from the carbon source and then rapidly cooling the coated substrate to cause graphene to precipitate on the surface of the metallic layer.

The metallic layer provided on the surface of the substrate may possess any desirable thickness provided it can withstand the subsequent processing conditions required to apply the graphene coating. It is preferred that the metallic layer possesses a thickness in the range 10 nm to 25 microns. This range is particularly preferred for a copper metallic layer. A layer thicker than 25 microns may be subject to sublimation during subsequent processing steps, while a layer thinner than 10 nm may lack sufficient integrity to enable a graphene coating to be grown on the surface of the metallic layer. If the metallic layer was any thinner then there is a risk that any carbon applied from the carbon source when growing the graphene coating may simply carbonise leading to an unsatisfactory graphene coating. The metallic layer may be provided on the surface of the substrate by any appropriate process. A mechanical deposition process, such as ball milling may be employed. Alternatively, an electrodeposition process may be used. Sputtering may be employed, particularly when a high level of accuracy is required to deposit the metallic layer on relatively small regions of the substrate, while electroplating may be employed, particularly when less accuracy is required or when larger regions of the surface of the substrate are to be coated. One way in which specific regions of the substrate may be coated, whilst leaving others uncoated, is to provide a mask to shield areas of the substrate underlying the mask from being provided with a layer of the metallic material.

Once the metallic layer has been provided on the surface of the substrate, it may then be subjected to heat treatment to prepare it for growth of the graphene coating. One such process is a heat treatment process, such as annealing, so as to modify the material of the metallic layer so that it has the appropriate grain structure upon which to provide the graphene coating. A more coarse grain size may be better than a finer grain size since this may offer the correct amount of potential energy to support the graphene deposition process. The particular temperature used to anneal the metallic layer will depend upon both the material from which the metallic layer is formed and the nature of the substrate. It is preferable to choose conditions which subject the metallic layer to sufficient heat treatment to develop the correct grain size, but to also ensure that the substrate is not subjected to conditions which could be detrimental to its physical and/or mechanical properties. It is preferred that the metallic layer is annealed at a temperature in the range 800 to 1000° C., more preferably 950 to 1000° C., higher temperatures in each range being most preferred. These temperatures are particularly suitable for iron-based substrates carrying any metallic layer, but they are particularly appropriate when using a copper or nickel layer on a steel substrate. An alternative preferred temperature range at which the metallic layer is annealed is 350 to 450° C., more preferably 350 to 400° C. These lower temperature ranges are preferred when annealing a metallic layer on an aluminium-based substrate.

The substrate with the metallic layer is preferably disposed in a reaction vessel, such as a clam furnace or the like, before being contacted with the source of carbon atoms to provide the graphene coating. In this way the graphene coating deposition process can be effected in a controlled environment. It is preferred that the reaction vessel is purged of oxygen before the metallic layer is contacted with the source of carbon atoms. Purging may be undertaken using any appropriate conditions. It may be achieved by flowing a gas, such as hydrogen or nitrogen through the reaction chamber for up to one hour. A different gas or shorter time periods, such as one minute or less, may be used.

Preferably, the metallic layer is contacted with the source of carbon atoms at an appropriate temperature to initiate growth of the graphene coating on the surface of the metallic layer whilst not detrimentally affecting the structure of the metallic layer or the underlying substrate. A preferred temperature range is 850 to 1050° C., a more preferred range being 850 to 950° C., temperatures towards the upper end of each range being most preferred. These temperature ranges are preferred for iron-based substrates. An alternative preferred temperature range is 400 to 600° C., more preferably 400 to 500° C. These lower temperature ranges are preferred for aluminium-based substrates. The metallic layer may be contacted with the source of carbon atoms over any suitable time period to ensure that a satisfactory graphene coating has developed on the metallic layer. A suitable time period may be 1 second to 60 minutes, more preferably 1 to 30 minutes, time periods towards the bottom end of the recited ranges being most preferred. Preferably the time period is sufficient to ensure that the graphene coating comprises at least one layer of graphene, or a plurality of layers of graphene. In some applications it may be preferred to provide just a single layer of graphene as a coating, but in other applications it may be desirable to provide a graphene coating incorporating two, three or more mono-layers of graphene. Contacting of the metallic layer with the source of carbon atoms is preferably effected in an inert atmosphere, for example an atmosphere comprising nitrogen or argon. Contacting of the metallic layer with the source of carbon atoms is preferably effected at atmospheric pressure. Whilst pressures above and below atmospheric pressure may be used as appropriate, it is commercially desirable to effect growth of the graphene coating at atmospheric pressure. Contacting of said metallic layer with the source of carbon atoms may be effected under conditions suitable to supersaturate the metallic layer with carbon. This method is preferred when the metallic layer comprises a material exhibiting a relatively high affinity for carbon, such as cobalt, nickel or iron.

It is preferred that the carbon atom source is a hydrocarbon gas. Any suitable hydrocarbon gas may be employed, preferred gases being methane, acetylene and propylene. The source of carbon atoms is preferably brought into contact with the metallic layer by use of a carrier gas, such as argon or nitrogen.

Once the graphene coating has been deposited the substrate may be examined to determine whether the preceding process steps have affected the substrate in any way that would necessitate a substrate rectification treatment. Such treatment may involve heating the substrate carrying the graphene coating to a temperature that is, for example, around 50 to 100° C. above the substrate's recommended normalising profile. Substrate rectification treatment, if required, may be carried out at any appropriate time during the process used to manufacture the final graphene coated component. A convenient time is after the graphene coating has been deposited but before any subsequent processing steps have been performed.

After the substrate has been provided with the graphene coating, the substrate is preferably then cooled to a temperature which is sufficiently low to ensure that the graphene coating does not “burn-off”. A suitable temperature is around 450° C. or less, preferably around 400° C. or less. It is preferred that the substrate carrying the graphene coating is not exposed to air or any other source of oxygen until its temperature has been brought down to the aforementioned temperature. This process is particularly preferred when the metallic layer comprises a material exhibiting a low affinity for carbon, such as copper or a copper-tin alloy. Cooling may be effected sufficiently rapidly to facilitate precipitation of graphene on the metallic layer. This method is preferred when the metallic layer comprises a material exhibiting a relatively high affinity for carbon, such as cobalt, nickel or iron.

It may be desirable in certain applications to subject the cooled substrate carrying the graphene coating to one or more further process steps. For example, it may be desirable to subject the cooled substrate to a further heat treatment process under conditions that are designed to enhance the physical and/or mechanical properties of the substrate.

After cooling the substrate it may be tested to ensure that a satisfactory graphene coating has been applied. One suitable method is Raman spectroscopy. If it is determined that the graphene coating does not meet the required specification, the substrate may be reheated and contacted with an additional amount of the carbon atom source. Alternatively, one or more layers of the unsatisfactory graphene coating, or the metallic layer, may be removed before the substrate is re-processed to provide a satisfactory metallic layer and graphene coating.

The substrate may comprise any desirable ferrous or iron-based material. For example, the substrate may be or may comprise cast iron or steel. Any desirable steel substrate may be coated using the above procedure. Preferred substrates comprise 1.4122 steel, 18CrNiMo7-6 steel, 19MnB4 steel, GS cast steel or En24 steel.

The substrate may be any component of a system which requires enhanced wear resistance, corrosion resistance and/or lubrication, such as a piston, piston ring or cam. By way of a further example, the substrate may be a component of power transmission machinery, such as a gear, coupling, bearing or sprocket, or it may be a component of a chain, such as a chain link member, a chain pin, bush or roller.

The second aspect of the invention provides a iron- or aluminium-containing substrate with a metallic layer and a graphene coating disposed on the metallic layer. The method according to the first aspect of the present invention is eminently suitable for manufacturing a coated substrate according to the second aspect of the present invention. For the avoidance of doubt, any of the features of the first aspect of the present invention recited above may also apply, where appropriate, to the coated substrate according to the second aspect of the present invention.

The third aspect of the present invention provides a chain in which one or more chain links and/or pins are/is provided with a graphene coating, while the fourth aspect of the present invention provides a chain in which a bush and/or roller are/is provided with a graphene coating. The method according to the first aspect of the present invention is, again, eminently suitable for providing these components of the chain with a graphene coating. Any one or more of the preferred features of the method according to the first aspect of the present invention may therefore be applied to the chain according to the third or fourth aspects of the present invention where appropriate. It is preferred that the graphene coating provided on the chain component(s) is disposed on a metallic layer which is provided on the appropriate surface of the chain component(s) so as to underlie the graphene coating. The surface or surfaces that are coated with graphene are preferably wear surfaces, surfaces which may be susceptible to corrosion during use of the chain and/or surfaces which are normally in need of lubrication during use of the chain. The chain may be of any type. For example the chain may be a roller bush chain as described in the specific embodiment set out below, or it may be for example a leaf chain, Galle chain, inverted tooth chain or a conveyor chain.

A specific embodiment of the present invention will now be described, by way of example only, with reference to the accompanying drawings in which:

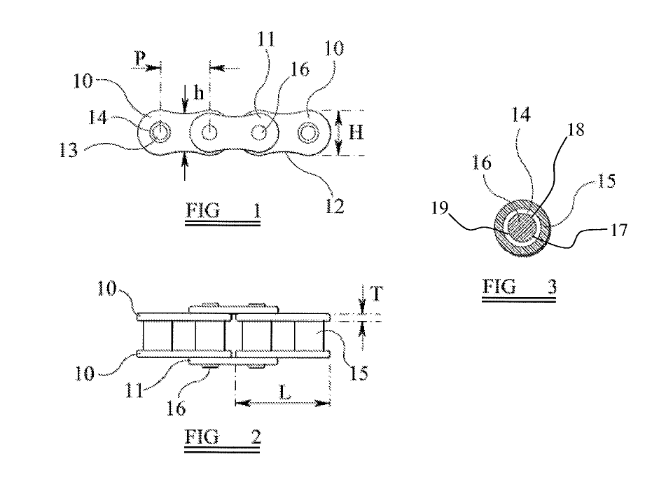

FIG. 1 is a side view of part of a roller chain according to a preferred embodiment of the present invention;

FIG. 2 is a plan view of the chain of FIG. 1;

FIG. 3 is a section through the pin, bush and roller of the chain of FIG. 1;

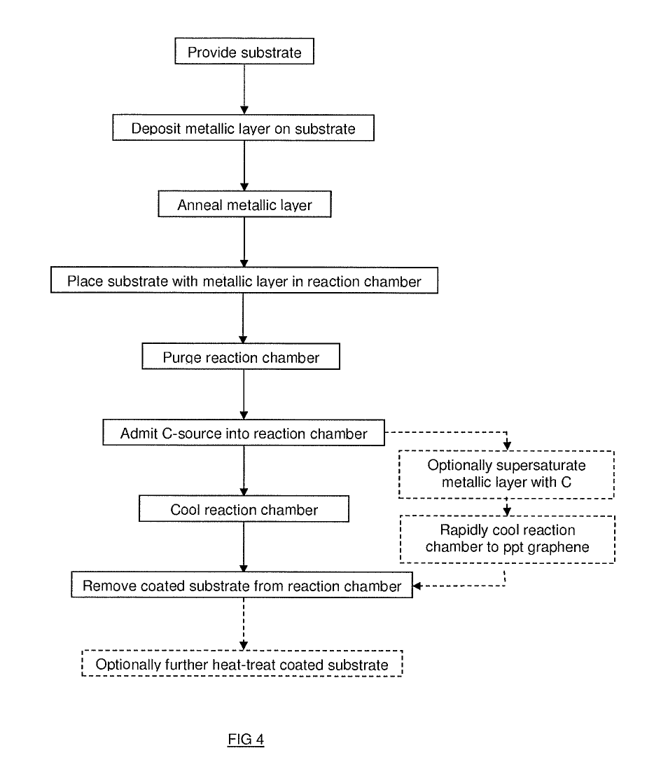

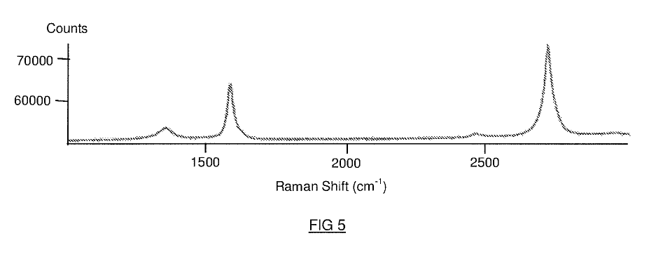

FIG. 4 is a flow diagram illustrating the steps in providing a graphene coating on a substrate according to an embodiment of the present invention; and

FIG. 5 is a Raman spectrum of a graphene coating applied to a substrate using a method according to an embodiment of the present invention.

Referring to FIGS. 1 to 3 of the drawings, a roller chain in accordance a preferred embodiment of the present invention comprises opposed pairs of inner link plates 10 that are arranged along the chain so as to alternate with opposed pairs of outer link plates 11. Each inner link plate 10 has a general length L, thickness T and height H and two spaced apertures 13 that are spaced apart by pitch distance P. The outer link plates 11 are of similar configuration but have a slightly reduced height and length. All the link plates 10, 11 are typically formed by blanking from a sheet of steel and have an outer profile that is rounded at each end and defines a central waisted portion 12 of reduced height h as is well known. The inner link plate apertures 13 receive parallel cylindrical bushes 14 in a fixed relationship (e.g. a press-fit connection) so that the opposed inner link plates 10 are connected together. A cylindrical roller 15 is rotatably disposed on each of the bushes 14. On each side of the chain adjacent pairs of inner link plates 10 are connected to the overlapping outer link plates 11 by transverse pins 16 that pass through aligned apertures 13 in each plate and through the bushes 14.

These pins 16 are an interference fit with the outer link plates 11 so that they are fixed relative thereto, but are free to rotate in the bushes so that the inner link plates 10 are free to articulate relative to the outer link plates 11.

The basic construction of the roller chain is essentially conventional, however, as shown in FIG. 3, the outer circumferential surface 17 of each pin 16 has been provided with a graphene coating 18 using the method according to the first aspect of the present invention. A copper layer exists between the surface 17 of the pin 16 and the graphene coating 18 however this is omitted from FIG. 3 for the sake of clarity. The graphene coating 18 affords a number of benefits. It acts as a wear and corrosion resistant coating, and also provides lubrication between the outer circumferential surface 17 of each pin 16 and the inner circumferential surface 19 of each corresponding bush 14.

The fundamental steps of the method used to apply the graphene coating 18 to the surface 17 of each pin are illustrated in FIG. 4.

The first step is to provide the substrate that is to be provided with a graphene coating. This may be an iron- or aluminium-based substrate, such as a pin of a roller bush chain manufactured of stainless steel. A layer of copper metal is then deposited on the surface of the pin upon which it is ultimately intended to provide a graphene coating.

The copper layer may be applied using any appropriate technique, but an electodeposition process is preferred. In the present embodiment, the copper layer is provided on the steel pin so as to have a thickness in the range 12 to 25 microns. The copper layer is then annealed by heating to 950 to 1000° C. for an appropriate period of time at atmospheric pressure.

The steel pin carrying the copper layer is then placed in a clam furnace reaction chamber. The reaction chamber is then purged with hydrogen for around 30 minutes. The substrate with the copper layer is then heated within the reaction chamber to a temperature of 950 to 1020° C. and contacted with methane for around 30 minutes. Methane is admitted into the reaction chamber using an argon or nitrogen carrier gas. The methane acts as a source of carbon atoms which then deposit on the metallic layer so as to form a graphene coating on the areas of the steel pin covered with the copper layer. Contacting of the copper layer with the carbon atom source is effected at atmospheric pressure.

The reaction chamber is then cooled so as to reduce the temperature of the substrate now carrying the graphene coating down to a temperature of around 400° C. or less. At this stage the coated pin can then be exposed to oxygen or removed from the reaction chamber for testing.

If the metallic layer comprises a compound, alloy or element with a relatively high affinity for carbon, such as cobalt, nickel or iron, it may be preferable to supersaturate the metallic layer with carbon during the carbon-source contacting stage and to then rapidly cool the coated substrate to encourage precipitation of graphene on the surface of the metallic layer.

Raman spectroscopy is employed to characterise the graphene coating. An exemplary spectrum of a coating applied to a substrate using the method set out above is shown in FIG. 5, which confirms the presence of graphene in the coating. If the coating does not meet the required specification then any one or more of the coating steps described above can be repeated. Additionally, the substrate can be examined to determine whether it has undergone any undesirable changes in structure or properties during processing. If so, the substrate may be subjected to a substrate rectification treatment. Such treatment may involve heating the substrate to a temperature that is about 50 to 100° C. above the normalising profile usually recommended for the particular substrate.

Optionally, the graphene-coated pin may be subjected to additional processing before assembly into the final chain. For example, the graphene-coated pin may be subjected to one or more further cycles of heat treatment to enhance the mechanical and/or physical properties of the steel in the pin.

The embodiment described above with reference to FIG. 4 is described by way of example only. It will be appreciated that the process conditions would be suitable for providing a graphene coating on any type of aluminium or steel substrate. Where reference is made to an aluminium substrate this should also be interpreted as encompassing substrates comprising aluminium or an aluminium alloy. The process conditions set out above are not dependent upon the size, shape or intended application of the substrate to which the graphene coating is being applied. The conditions set out above are, however, eminently suitable for providing a graphene coating on components of chains, sprockets and the like manufactured from steel.

1. A method for applying a graphene coating to a substrate comprising iron or aluminum, the method comprising:
a. providing a metallic layer on a surface of the substrate; and
b. contacting said metallic layer with a source of carbon atoms to provide a graphene coating on the metallic layer.

2. A method according to claim 1, wherein the metallic layer comprises a closed D-shell transition metal.

3-4. (canceled)

5. A method according to claim 1, wherein the metallic layer comprises a metal selected from the group consisting of cobalt, iron, copper, tin, nickel, silver and gold.

6. A method according to any preceding claim 1, wherein the metallic layer comprises two or more elements, at least two of said two or more elements combined in an alloy.

7. (canceled)

8. A method according to claim 6, wherein said alloy contains copper and tin.

9. (canceled)

10. A method according to claim 6, wherein said alloy exhibits a melting point that is no more than around 100° C. below the temperature at which growth of the graphene layer is to be effected.

11. A method according to claim 6, wherein at least two of said two or more elements are provided in separate layers within said metallic layer.

12. A method according to claim 1, wherein the metallic layer is selected from the group consisting of and adhesion layer, a barrier layer and a catalytic growth layer.

13-16. (canceled)

17. A method according to claim 1, wherein the substrate with the metallic layer provided thereon is subjected to heat treatment before being contacted by the source of carbon atoms.

18. A method according to claim 17, wherein said heat treatment comprises annealing.

19. (canceled)

20. A method according to claim 18, wherein said annealing is effected at a temperature in a range selected from the group consisting of 800 to 1000° C., 950 to 1000° C., and 350 to 450° C.

21-27. (canceled)

28. A method according to claim 1, wherein contacting of said metallic layer with the source of carbon atoms is effected at a temperature selected from the group consisting of 850 to 1050° C., 850 to 950° C., and 400 to 600° C.

29-37. (canceled)

38. A method according to claim 1, wherein contacting of said metallic layer with the source of carbon atoms is effected under conditions suitable to supersaturate the metallic layer with carbon.

39. A method according to claim 1, wherein said source of carbon atoms is a hydrocarbon gas.

40. (canceled)

41. A method according to claim 1, wherein after the substrate has been provided with the graphene coating the substrate is cooled to a temperature below 450° C.

42. (canceled)

43. A method according to claim 41, wherein said cooling is effected sufficiently rapidly to facilitate precipitation of graphene on the metallic layer.

44-46. (canceled)

47. A method according to claim 1, wherein the substrate comprises a material selected from the group consisting of cast iron and steel.

48. (canceled)

49. A substrate comprising iron or aluminium with a metallic layer on a surface of the substrate and a graphene coating disposed on said metallic layer.

50. A chain comprising a plurality of chain link members and a plurality of pins interconnecting said link members, a surface of at least one of the chain link members and/or a surface of at least one of the pins being provided with a graphene coating.

51. A chain comprising a plurality of chain link members, a plurality of pins interconnecting said link members, and a bush and/or roller supported on one or more of the pins, a surface of the bush and/or roller being provided with a graphene coating.

52-55. (canceled)
